(19) United States
(12) Patent Application Publication
(10) Pub. No.: US 2008/0101120 A1
(43) Pub. Date: May 1, 2008

(54) METHOD OF PROGRAMMING MULTI-PAGES AND FLASH MEMORY DEVICE OF PERFORMING THE SAME

(75) Inventors: Ki-Tae Park, Hwaseong-si (KR); Ki-Nam Kim, Seoul (KR); Yeong-Taek Lee, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/877,302

(22) Filed: Oct. 23, 2007

(30) Foreign Application Priority Data
Oct. 23, 2006 (KR) 10-2006-0102782

(51) Int. Cl. G11C 16/04

(52) U.S. Cl. 365/185.12; 365/185.11

(57) ABSTRACT

In programming multi-pages in a flash memory device, a first page group and a second page group are formed with respect to each of at least one memory plane by grouping page buffers such that logical odd bitlines and logical even bitlines correspond to one of the first page group and the second page group, respectively. Program data corresponding to at least one page coupled to a selected wordline are loaded, and then a program voltage is applied to the selected wordline. A plurality of pages, including at least two pages pertaining to the same memory plane, can be simultaneously programmed and a row-coupling disturbance can be reduced.

### CROSS-REFERENCE TO RELATED APPLICATIONS

This application claims priority under 35 USC § 119 to Korean Patent Application No. 10-2006-0102782, filed on Oct. 23, 2006 in the Korean Intellectual Property Office (KIPO), the disclosure of which is incorporated herein in its entirety by reference.

### FIELD OF THE INVENTION

The present invention relates to a non-volatile memory device, and more particularly to a method of programming multi-pages, a flash memory device of performing the method of programming multi-pages, and an apparatus including the flash memory device.

### BACKGROUND OF THE INVENTION

A semiconductor memory device is typically classified into a non-volatile memory device that maintains stored data when power is off, and a volatile memory device that loses stored data even though power is off. The non-volatile memory device includes an electrically erasable and programmable read-only memory (EEPROM), in which stored data can be electrically erased and new data can be reprogrammed.

Operations of the EEPROM include a program mode for writing data into a memory cell, a read mode for read out the data stored in the memory cell, and an erase mode for initializing a memory cell by deleting the stored data.

In a flash memory device pertaining to the EEPROM, erasing operation is performed per memory block or sector, and programming operation is performed per page corresponding to a plurality of memory cells commonly coupled to a word line. The flash memory device may be classified, according to a configuration of a memory cell array, into a NAND flash memory device in which cell transistors are coupled parallel between a bitline and a ground electrode and a NOR flash memory device in which cell transistors are coupled serially between a bit line and a ground electrode. The NAND flash memory device has a higher speed of programming and erasing than the NOR flash memory device, but cannot access per byte in the reading operation and the programming operation.

FIG. 1 is a circuit diagram illustrating a conventional flash memory device.

Referring to FIG. 1, the conventional flash memory device 100 includes a memory cell array 110, a bitline selection circuit 120 and a page buffer block 130.

The memory cell array 110 may include a plurality of memory planes. Even though only one memory block in one memory plane is illustrated in FIG. 1 for convenience, each memory plane may include a plurality of memory block arranged in a column direction.

The memory block of the memory cell array 110 includes a plurality of memory cells M1, M2 and Mm arranged in a matrix form, in which the memory cells M1, M2 and Mm are coupled to respective wordlines WL1, WL2 and WL3. The memory cells M1, M2 and Mm in each column form a NAND string. The NAND string is coupled between one of bitlines BLe and BLo and a common source line CSL through a string selection transistor SST and a ground selection transistor GST. Electrical connections of the NAND string to the bitlines BLe and BLo and the common source line CSL are controlled by signals input to gates of the string selection transistor SST and the ground selection transistor GST, respectively. In the programming operation, one wordline is selected in response to a row address signal such that a program voltage is applied to a selected wordline and a pass voltage is applied to unselected word lines. In response to a column address signal, a page consisting of memory cells in the common wordline is selected.

As illustrated in FIG. 1, the bitlines BLe and BLo are classified into even bitlines BLe1, BLe2 and BLen and odd bitlines BLo1, BLo2 and BLon. As such, each row includes one page coupled to the even bitlines BLe1, BLe2 and BLen and the other page coupled to the odd bitlines BLo1, BLo2 and BLon.

The bitline selection circuit 120 selects one of the two pages and controls data transfer between the page buffer block 130 and the bitlines BLo and BLe.

A pair of adjacent bitlines BLek and BLok (k=1, 2, . . . , n) is commonly coupled to the respective page buffer 131 or the page register in the page buffer block 130, and one of the even bitline BLek and the odd bitline BLok is selected by an alternative switching operation of the transistors S1 and S2. The switch operation of the transistors is controlled by the signals input to the gates coupled to the selection lines BSL1 and BSL2.

Each page buffer 131 operates as a sense amplifier, a latch and/or a writing driver according to the operation mode. In the programming operation, the page buffers 131 latches the program data corresponding to the selected page, and the latched data are transferred to the bitlines selected by the bitline selection circuit 120.

FIG. 2 is a diagram illustrating a conventional method of programming multi-pages in multi-planes.

The method of programming multi-pages in a flash memory device including two memory planes 110a and 110b is illustrated in FIG. 1. Each of the memory plane 110a and 110b includes a plurality of memory blocks (e.g., 2048 memory blocks) arranged in a column direction. One memory block and one row therein per memory plane are selected by a row decoder. Each of the memory plane 110a and 110b are coupled to the respective page buffer block through the bitline selection circuit as illustrated in FIG. 1.

Referring to FIG. 2, commands 80h, 11h, 81h and 10h are sequentially input at time points t1, t2, t3 and t4, to program two pages respectively pertaining to the different memory planes 110a and 110b. The commands 80h and 81h are a data input command, for a first cycle and a second cycle, respectively, to indicate that data are input. The command 10h is a page program command to indicate that a program voltage is applied to a selected wordline. The command 11h is a dummy command to defer applying the program voltage to the selected wordline. In a single page program mode, the command 11h is replaced with the command 10h.

After the command 80h, row and column address signals of a first page pertaining to the first memory plane 110a are input, and program data corresponding the first page are loaded into the page buffers coupled to the first memory plane 110a in response to the column address. After the command 81h, row and column address signals of a second page pertaining to the second memory plane 110b are input, and program data corresponding the second page are loaded into the page buffers coupled to the second memory plane 110b in response to the column address. The row addresses of the first and second pages are identical, and thus the first and second pages pertaining to the different memory planes are simultaneously programmed.

FIG. 3 is a diagram for describing a coupling disturbance in a conventional flash memory device.

As illustrated in FIG. 3, two pages pertaining to the different memory planes 110a and 110b can be simultaneously programmed in a conventional flash memory device having such a configuration of FIG. 1. In this case, a row-coupling disturbance is caused due to a coupling capacitance Cx between a memory cell Me coupled to a physical even bitline and an adjacent memory cell Mo coupled to a physical odd bitline. When the memory cells Me are programmed, programming of the memory cells Me are affected by the state of the adjacent memory cells Mo and thus a margin of a read voltage for reading out data stored in the memory cells Me and Mo is reduced. It is referred to as the row-coupling disturbance that a threshold voltage distribution of the memory cell that is programmed is affected by the state of the adjacent memory cell.

In the conventional flash memory device 100, the physical even bitline and the physical odd bitline form a pair and the pair is coupled to one page buffer and the physical even bitlines form one page and the physical odd bitlines form another page. Accordingly the physical even bitlines or the physical odd bitlines can be selectively programmed in one memory plane, and thus the row-coupling disturbance is increased. A subsequent programming is required to correct the change of the threshold voltage distribution due to the row-coupling disturbance and thus performance of the flash memory device is degraded.

In addition to the problems associated with the row-coupling disturbance, the conventional method cannot program multi-pages with respect to a single memory plane even though multi-pages respectively pertaining to a plurality of memory planes.

### SUMMARY OF THE INVENTION

Accordingly, the present invention is provided to substantially obviate one or more problems due to limitations and disadvantages of the related art.

Some example embodiments of the present invention provide a method of programming multi-pages, capable of reducing a row-coupling disturbance and simultaneously programming a plurality of pages pertaining to a common memory plane.

Some example embodiments of the present invention provide a flash memory device, capable of reducing a row-coupling disturbance and simultaneously programming a plurality of pages pertaining to a common memory plane.

Some example embodiments of the present invention provide an apparatus including the flash memory device.

In a method of programming multi-pages in a flash memory device, in accordance with some example embodiments of the present invention, a first page group and a second page group are formed with respect to each of at least one memory plane by grouping page buffers such that logical odd bitlines and logical even bitlines correspond to one of the first page group and the second page group, respectively. Program data corresponding to at least one page coupled to a selected wordline are loaded, and then a program voltage is applied to the selected wordline.

The first page group and the second page group may be formed by connecting the page buffers to each of a physical odd bitline and a physical even bitline, respectively.

Memory cells coupled to adjacent physical odd and even bitlines may be simultaneously programmed.

Two or more pages may be simultaneously programmed with respect to a single memory plane of the at least one memory plane.

In some embodiments, the first page group and the second page group may be formed by partitioning each of the at least one memory plane into logical odd bitline blocks and logical even bitline blocks that are alternately arranged in a row direction.

The at least one memory plane may include a first memory plane. First program data are loaded into the page buffers corresponding to the first page group of the first memory plane, and second program data are loaded into the page buffers corresponding to the second page group of the first memory plane. Then the program voltage is applied to the selected wordline.

The at least one memory plane may further include a second memory plane. In this case, third program data may be further loaded into the page buffers corresponding to the first page group of the second memory plane, and then the program voltage is applied to the selected wordline. Fourth program data may be further loaded into the page buffers corresponding to the second page group of the second memory plane, and then the program voltage is applied to the selected wordline.

The at least one memory plane may include N memory planes, where N is a natural number, the program data may be loaded into the page buffers corresponding to at least one page of 2N pages, where each of the 2N pages respectively corresponds to the first page groups and the second page groups of the N memory plane and then the program voltage is applied to the selected wordline.

In some example embodiments of the present invention, a flash memory device includes at least one memory plane, at least one first page buffer block and at least one second page buffer block. Each memory plane is partitioned into logical odd bitline blocks and logical even bitline blocks that are alternately arranged in a row direction. The logical odd bitline blocks may correspond to a first page group, and the logical even bitline blocks may correspond to a second page group. Each first page buffer block includes page buffers that are respectively connected to bitlines of the logical odd bitline blocks, and each second page buffer block includes page buffers that are respectively connected to bitlines of the logical even bitline blocks.

Each logical odd bitline block and each even bitline block may consist of adjacent physical odd and even bitlines, respectively.

Each memory plane may be partitioned into the logical odd bitline blocks and the logical even bitline blocks based on boundaries of dummy bitlines.

The at least one memory plane may include a first memory plane, and at least one page of a first page and a second page coupled to a common wordline may be simultaneously programmed, where the first page pertains to the first page group of the first memory plane and the second page pertains to the second page group of the first memory plane.

The at least one memory plane may include N memory planes, N being a natural number, and at least one page of 2N pages coupled to a common wordline may be simultaneously programmed, where the 2N pages respectively pertain to the first page groups and the second page groups of the N memory plane.

The first page block may be disposed at an opposite position of the second page block in a column direction with respect to the corresponding memory plane.

The first page buffer block may be divided into a first sub-block connected to physical even bitlines of the first page buffer block and a second sub-block connected to physical odd bitlines of the first page buffer block. The second page buffer block may be divided into a third sub-block connected to physical even bitlines of the second page buffer block and a fourth sub-block connected to physical odd bitlines of the second page buffer block. In this case the first and third sub-blocks may be disposed at an opposite position of the second and fourth sub-blocks in a column direction with respect to the corresponding memory plane.

In some example embodiments of the present invention, an apparatus includes a flash memory device of performing the method of programming multi-pages, and a memory controller configured to control the flash memory device.

Accordingly a plurality of pages including at least two pages in the same memory plane may be simultaneously programmed, and a row-coupling disturbance may be reduced, thereby improving performance of devices and systems.

### BRIEF DESCRIPTION OF THE DRAWINGS

FIG. 1 is a circuit diagram illustrating a conventional flash memory device.

FIG. 2 is a diagram illustrating a conventional method of programming multi-pages in multi-planes.

FIG. 3 is a diagram for describing a coupling disturbance in a conventional flash memory device.

FIG. 4 is a diagram illustrating a method of programming multi-pages according to an example embodiment of the present invention.

FIG. 5 is a diagram for describing an effect of a method of programming multi-pages according to an example embodiment of the present invention.

FIG. 6 is a diagram illustrating a method of programming multi-pages according to an example embodiment of the present invention.

FIG. 7 is a diagram illustrating an example connection-relation of page buffers in a flash memory device according to an example embodiment of the present invention.

FIG. 8 is a block diagram illustrating a flash memory device according to an example embodiment of the present invention.

FIG. 9 is a diagram illustrating an example configuration of the memory plane in FIG. 8.

FIG. 10 is a block diagram illustrating a flash memory device according to an example embodiment of the present invention.

FIG. 11 is a diagram illustrating an example connection-relation of page buffers in a flash memory device according to an example embodiment of the present invention.

### DESCRIPTION OF THE EMBODIMENTS

Embodiments of the present invention now will be described more fully with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

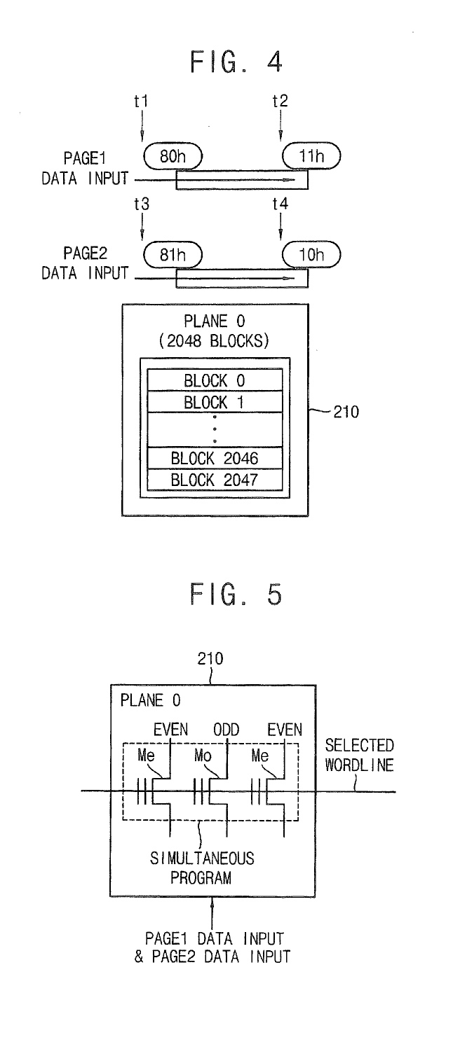

FIG. 4 is a diagram illustrating a method of programming multi-pages according to an example embodiment of the present invention.

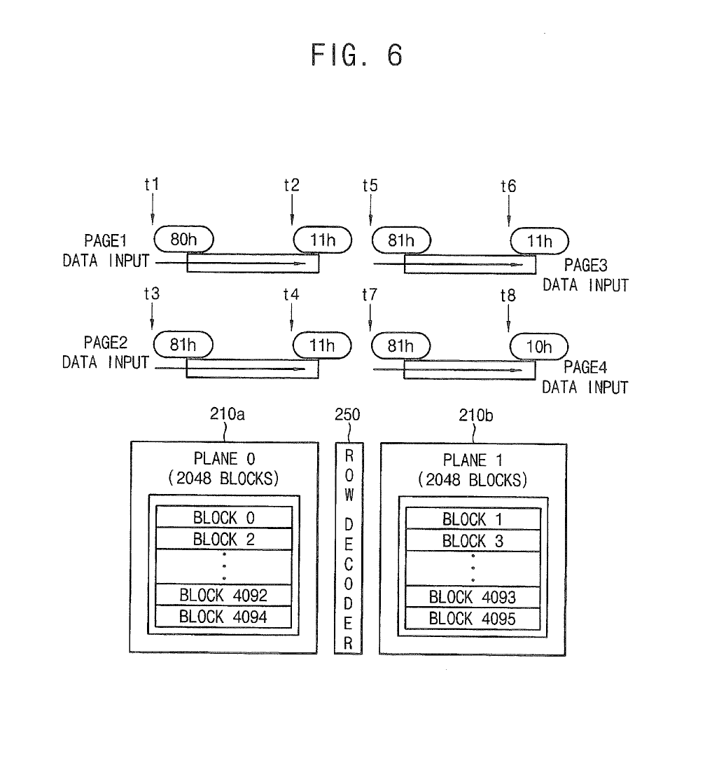

A method of programming multi-pages in a memory plane 210 is described with reference to FIG. 4. The method of programming multi-pages according to example embodiments is not limited to a flash memory device including a single memory plane and can be adaptable to a flash memory device including two or more memory planes as will be described with reference to FIG. 6.

Referring to FIG. 4, commands 80h, 11h, 81h and 10h are sequentially input at time points t1, t2, t3 and t4, to program two pages respectively pertaining to the same memory planes 210. The commands 80h and 81h are a data input command to indicate that data are input, for example, through input/output pins. The command 10h is a page program command to indicate that a program voltage is applied to a selected wordline. The command 11h is a dummy command to defer applying the program voltage to the selected wordline. When a single page is programmed, the command 11h is replaced with the command 10h.

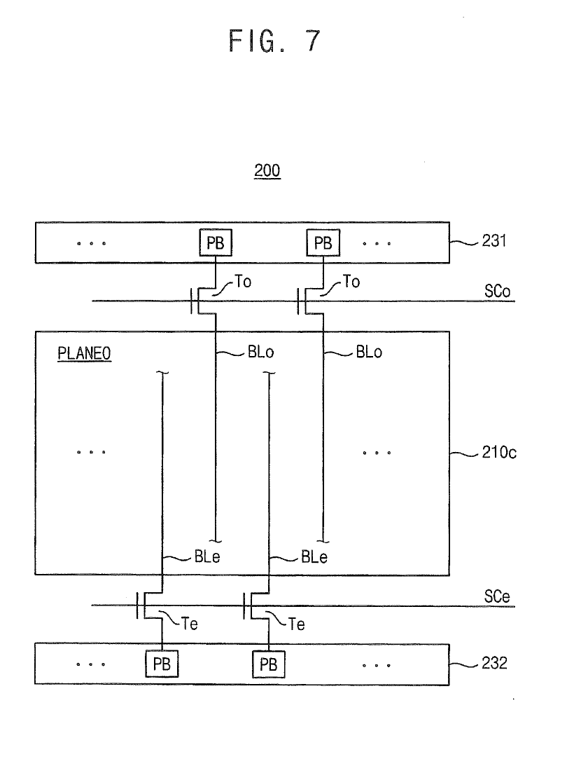

After the command 80h, row and column address signals of a first page pertaining to the memory plane 210 are input, and program data corresponding the first page are loaded into page buffers, for example, which are included in a page buffer block 231 of FIG. 7. After the command 81h, row and column address signals of a second page pertaining to the same memory plane 210 are input, and program data corresponding the second page are loaded into other page buffers, for example, which are included in a page buffer block 232 of FIG. 7. The row addresses of the first and second pages are identical, and thus the first and second pages pertaining to the same memory plane 210 are simultaneously programmed.

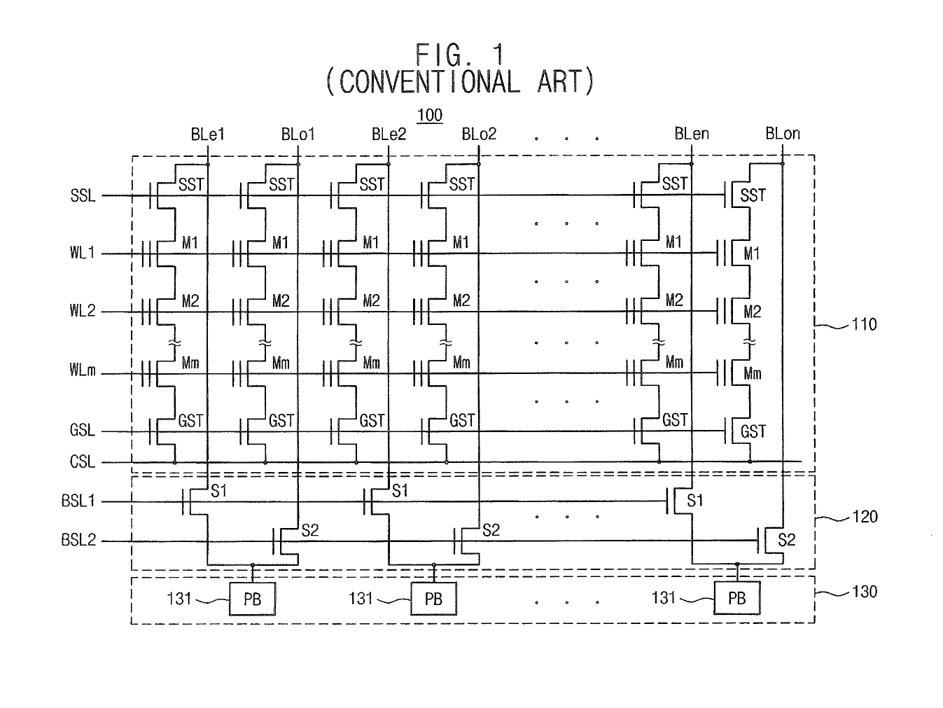

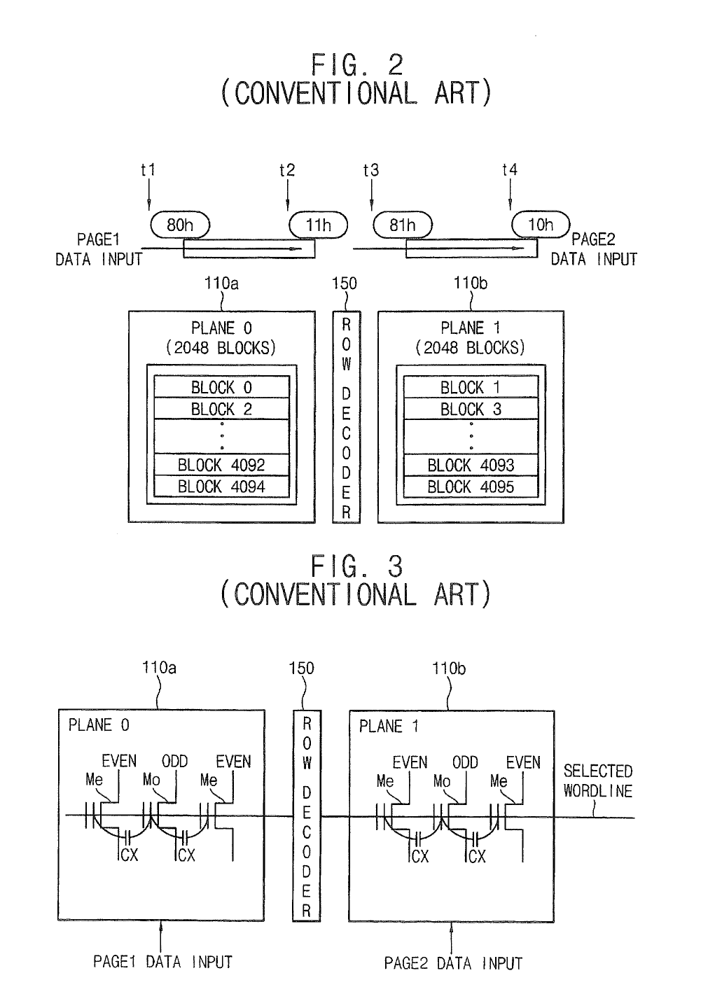

In the conventional flash memory device as illustrated in FIG. 1, two pages pertaining to the different memory planes 110a and 110b can be simultaneously programmed. In contrast, in a flash memory device as described later, two or more pages pertaining to the same memory planes can be simultaneously programmed. Furthermore, the row-coupling disturbance as above described can be reduced. As a result, performance of the flash memory device can be enhanced. In addition, the method of programming multi-pages according to example embodiments of the present invention can be performed without significantly changing the commands.

Even though the method of programming two pages in the same memory plane referring to FIG. 4, it is understood to those skilled in the art that three or more pages in the same memory plane may be simultaneously programmed when a flash memory device is configured such that each memory plane has three or more pages per row. In this case, program data for three or more pages are loaded and then a program voltage is applied to a selected wordline.

FIG. 5 is a diagram for describing an effect of a method of programming multi-pages according to an example embodiment of the present invention.

In accordance with the method described referring to FIG. 4, when two pages are simultaneously programmed, a program voltage is applied to a selected wordline after program data of two pages pertaining to the same memory plane 210. Therefore adjacent memory cells Me and Mo respectively coupled to a physical even bitline and a physical odd bitline are simultaneously programmed, and thus the row-coupling disturbance described referring to FIG. 3 can be reduced.

FIG. 6 is a diagram illustrating a method of programming multi-pages according to an example embodiment of the present invention.

A method of simultaneously programming three or four pages in two memory planes 210a and 210b is described with reference to FIG. 6. Repeated description with respect to FIG. 4 is omitted.

Even though a single row decoder 250 is illustrated in FIG. 6, each row decoder may be assigned to memory planes, respectively, or a single row decoder may be commonly assigned to three of more memory planes. The position of the row decoder may be variously changed depending on a layout of a flash memory device.

Referring to FIG. 6, commands 80h, 11h, 81h, 11h, 81h, 11h, 81h and 10h are sequentially input at time points t1, t2, t3, t4, t5, t6, t7 and t8, to program four pages pertaining to the two memory planes 210a and 210b. Program data of two pages pertaining to the memory plane 210a are loaded in the corresponding page buffers, and program data of two pages pertaining to the memory plane 210b are loaded in the corresponding page buffers. After the program data corresponding to the four pages are loaded, a program voltage is applied to a selected wordline and a pass voltage is applied to unselected wordlines, responding to the command 10h. The row addresses of the four pages are identical, and the four pages corresponding to the selected wordline are simultaneously programmed.

When three pages are simultaneously programmed, the dummy command 11h at time point t6 is replaced with the page program command 10h. As a result, the program voltage is applied to the selected wordline after the program data corresponding to the three pages are loaded.

Even though the method of programming three or four pages in the two memory planes referring to FIG. 6, it is understood to those skilled in the art that more pages may be simultaneously programmed when a flash memory device includes three or more memory planes and/or is configured such that each memory plane has three or more pages per row.

FIG. 7 is a diagram illustrating an example connection-relation of page buffers in a flash memory device 200 according to an example embodiment of the present invention.

For convenience of description, only one memory plane 210c and corresponding page buffer blocks 231 and 232 are illustrated and memory cells are omitted in FIG. 7.

For each memory plane 210c, page buffers PB or page registers are grouped to form a first page group and a second page group such that logical odd bitlines and logical even bitlines correspond to one of the first page group and the second page group, respectively. For example, physical odd bitlines BLo may directly correspond to logical odd bitlines corresponding to the first page group and physical even bitlines BLe may directly correspond to logical even bitlines corresponding to the second page group, as illustrated in FIG. 7. Program data of the first page group are loaded in the first page buffer blocks 231, and program data of the second page group are loaded in the second page buffer blocks 232, When switch control signals SCo and SCe are activated, transistors To and Te are turned on and thus voltages according to latched data in the page buffers PB are applied to the bitlines BLo and BLe, respectively. Then a program voltage is applied to a selected wordline to program memory cells corresponding to pages to be written.

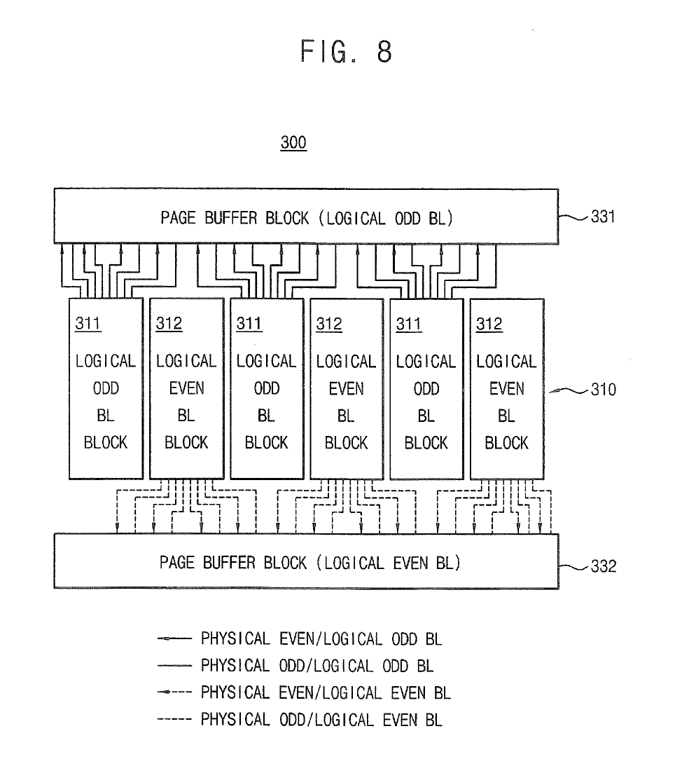

In the flash memory device 200, each page buffer PB may be coupled to one physical odd bitline BLo and one physical even bitline BLe, respectively, to loading program data of two pages, whereas one page buffer is commonly coupled to a pair of bitlines in the flash memory device in FIG. 1. Even though FIG. 7 illustrates one example such that the physical odd bitlines BLo form one page group and the physical even bitlines BLe form another page group, the page groups may be various formed, for example, as will be described referring to FIG. 8.

FIG. 8 is a block diagram illustrating a flash memory device according to an example embodiment of the present invention.

Referring to FIG. 8, the flash memory device 300 includes a memory plane 310 and page buffer blocks 331 and 332. In some example embodiments, the flash memory device 300 may include a plurality of memory planes as illustrated in FIG. 8 and the corresponding number of page buffer blocks.

The memory plane 310 is partitioned into logical odd bitline blocks 311 corresponding to a first page group and logical even bitline blocks 312 corresponding to a second page group. The logical odd bitline blocks 311 and the logical even bitline blocks 312 are alternately arranged in a row direction. Each logical odd bitline block 311 and each even bitline block 312 may consist of a predetermined number of adjacent physical odd and even bitlines, respectively. “Physical odd” and “physical even” represents substantial order of the bitlines as the odd and even bitlines BLo and BLe illustrated in FIG. 7.

The first page buffer block 332 includes page buffers that are respectively connected to bitlines of the logical odd bitline blocks 311, and the second page buffer block 332 includes page buffers that are respectively connected to bitlines of the logical even bitline blocks 312. As such, the first and second page groups may be formed by connecting each page buffer to the respective bitlines and by grouping the page buffers.

In case of forming the memory plane 300 as illustrated in FIG. 8, adjacent memory cells in each of the logical blocks 311 and 312 are simultaneously programmed even though one page is programmed, and thus the row-coupling disturbance can be reduced.

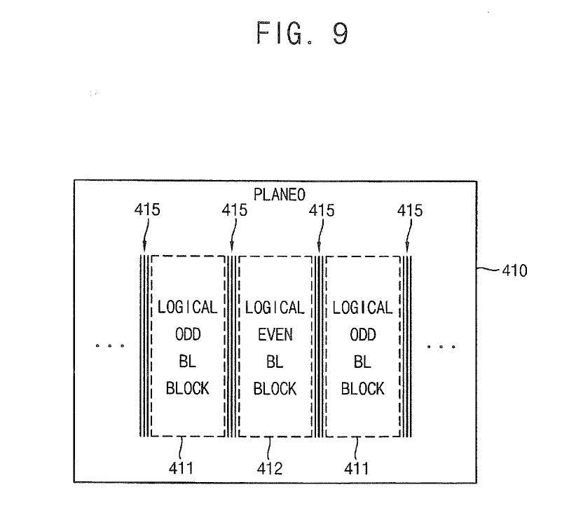

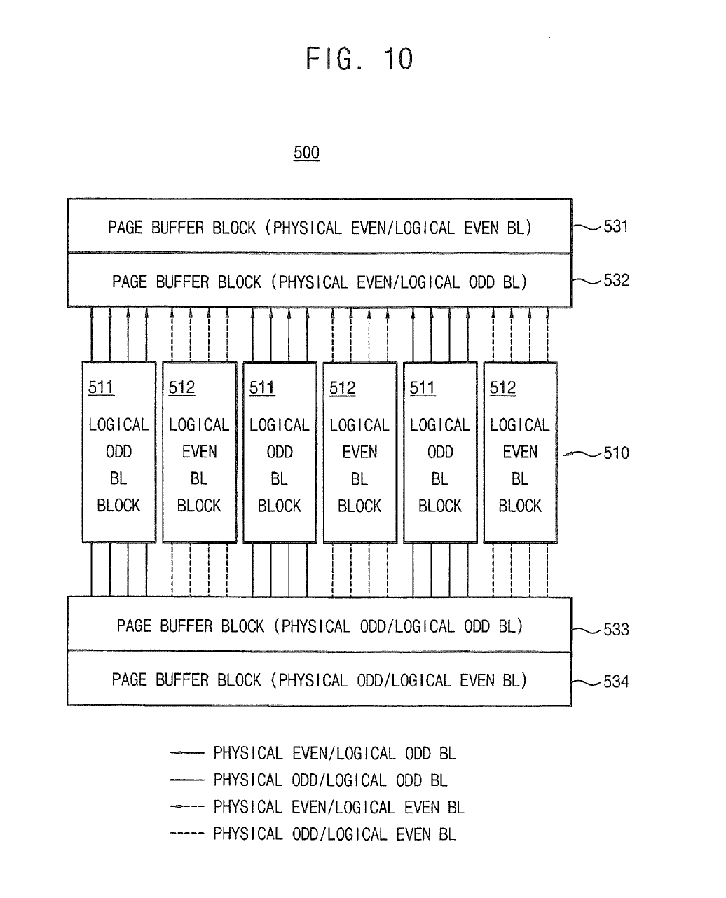

FIG. 9 is a diagram illustrating an example configuration of the memory plane in FIG. 8.

As illustrated in FIG. 9, the memory plane 410 may be partitioned into the logical odd bitline blocks 411 and the logical even bitline blocks 412 based on boundaries of dummy bitlines 415. In general the dummy bitlines are formed per a predetermined number of bitlines for contact of common source lines and pocket p-wells.

In case of forming the logical blocks 411 and 412 using the dummy bitlines 415, the row-coupling disturbance between the logical blocks 411 and 412 can be further reduced.

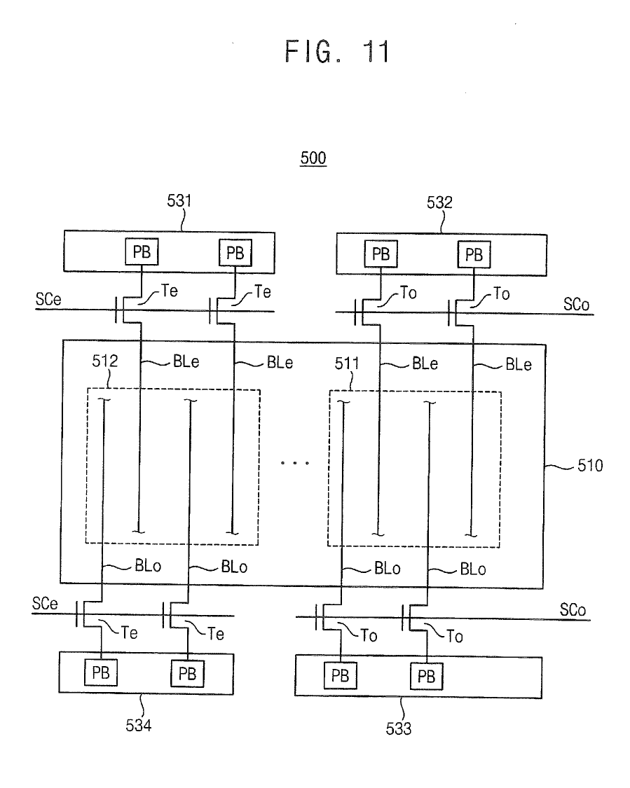

FIG. 10 is a block diagram illustrating a flash memory device according to an example embodiment of the present invention.

Referring to FIG. 8, the flash memory device 500 includes a memory plane 510 and sub-blocks 531, 532, 533 and 534. Repeated description with respect to FIG. 8 is omitted.

A first page buffer block includes page buffers that are respectively connected to bitlines of the logical odd bitline blocks 511, and the first page buffer block is divided into a first sub-block 532 and a second sub-block 533. A second page buffer block includes page buffers that are respectively connected to bitlines of the logical even bitline blocks 512, and the second page buffer block is divided into a third sub-block 531 and a fourth sub-block 534. The first sub-block 532 is connected to physical even bitlines of the logical odd bitline blocks 511 and the second sub-block 533 is connected to physical odd bitlines of the logical odd bitline blocks 511. The third sub-block 531 is connected to physical even bitlines of the logical even bitline blocks 512 and the fourth sub-block 534 is connected to physical odd bitlines of the logical even bitline blocks 512.

When a page pertaining to the logical odd bitline block 511 is programmed, the first sub-block 532 and the second sub-block 533 are enabled. When another page pertaining to the logical even bitline block 512 is programmed, the third sub-block 531 and the fourth sub-block 534 are enabled. When two pages are simultaneously programmed, the first and second sub-blocks 532 and 534 and the third and fourth sub-blocks 531 and 534 are all enabled. As such, the first and second page groups may be formed by connecting each page buffer to the respective bitlines and by grouping the page buffers.

The first sub-block 532 and the third sub-block 533, which are coupled to the physical even bitlines, may be disposed over the memory plane 510, and the second sub-block 533 and the fourth sub-block 534, which are coupled to the physical odd bitlines, may be disposed under the memory plane 510, As such some sub-blocks may be disposed at an opposite position of the other sub-blocks in a column direction with respect to the corresponding memory plane, considering a layout margin of the flash memory device 500.

FIG. 11 is a diagram illustrating an example connection-relation of page buffers in a flash memory device according to an example embodiment of the present invention.

For convenience of description, only one memory plane 510 and corresponding page buffer blocks including sub-block 531, 532, 533 and 534 are illustrated and memory cells are omitted in FIG. 7.

For each memory plane 500, page buffers PB or page registers are grouped to form a first page group and a second page group such that logical odd bitlines and logical even bitlines correspond to one of the first page group and the second page group, respectively. For example, a first sub-block 532 includes page buffers PB that are connected to physical even bitlines BLe of the logical odd bitline blocks 511 and a second sub-block 533 includes page buffers PB that are connected to physical odd bitlines of the logical odd bitline blocks 511. A third sub-block 531 includes page buffers PB that are connected to physical even bitlines of the logical even bitline blocks 512 and a fourth sub-block 534 includes page buffers PB that are connected to physical odd bitlines of the logical even bitline blocks 512.

Program data of the first page group are loaded in the first page buffer blocks including the first sub-block 532 and the second sub-block 533, and program data of the second page group are loaded in the second page buffer blocks including the third sub-block 531 and the fourth sub-block 534, When switch control signals SCo and SCe are activated, transistors To and Te are turned on and thus voltages according to latched data in the page buffers PB are applied to the bitlines BLo and BLe, respectively. Then a program voltage is applied to a selected wordline to program memory cells corresponding to pages to be written.

A flash memory device, which is configured to perform a method of programming multi-pages as described with reference to FIGS. 4 and 6, may be included in various apparatuses and systems.

For example, an apparatus according to some example embodiments of the present invention may include a flash memory device of performing the method of programming multi-pages as described with reference to FIGS. 4 and 6, and a memory controller configured to control the flash memory device.

The apparatus including the flash memory device and the memory controller may be mounted in a package. Function blocks and peripheral circuits may be further included in the package. For example, the apparatus may be mounted in a package such as Package on Package (PoP), Ball Grid Arrays (BGAs), Chip Scale Packages (CSPs), Plastic Leaded Chip Carrier (PLCC), Plastic Dual In-Line Package (PDIP), Die in Waffle Package, Die in Wafer Form, Chip On Board (COB), Ceramic Dual In-Line Package (CERDIP), Plastic Metric Quad Flat Package (MQFP), Thin Quad Flat Package (TQFP), Small Outline Integrated Circuit (SOIC), Shrink Small Outline Package (SSOP), Thin Small Outline Package (TSOP), Thin Quad Flat Package (TQFP), System In Package (SIP), Multi Chip Package (MCP), Wafer-level Fabricated Package (WFP), Wafer-Level Processed Stack Package (WSP), etc.

For example, the apparatus including the flash memory device of performing the method of programming multi-pages may be a memory card. The memory card may communicate with an external device (e.g. a host) through at least one interface among Universal Serial Bus (USB), Multimedia Card (MMC), Peripheral Component Interconnect-Express (PCI-E), Serial Advanced Technology Attachment (SATA), Parallel Advanced Technology Attachment (PATA), Small Computer System Interface (SCSI), Enhanced Small Device Interface (ESDI), Integrated Drive Electronics (IDE), etc.

For example, the apparatus including the flash memory device of performing the method of programming multi-pages may be a mobile device such as a cellular phone, a personal digital/data assistant (PDA), a digital camera, a portable game console and MP3 player. In case of the mobile device, the flash memory device therein may store codes for an operation the mobile device as well as data.

For example, the flash memory device of performing the method of programming multi-pages may be adaptable to a home application such as a high definition television (HDTV), a digital video disk, a digital versatile disc (DVD), a router, Global Positioning System (GPS), etc.

For example, the flash memory device of performing the method of programming multi-pages may be adaptable to a computing system. In case of a computing system, the apparatus may further include a microprocessor electrically coupled to a bus, a user interface, and a modem such as a baseband chipset. The flash memory device may store data of at least one bit, which is processed by the microprocessor, through the memory controller. In case that the computing system is mobile device, a battery for supply an operating voltage of the computing system may be further included. It will be understood to those skilled in the art that the computing system may further include an application chipset, a camera image processor (CIS), and/or a mobile DRAM.

For example, the flash memory device of performing the method of programming multi-pages may be adaptable to a solid state drive/disk (SSD), which requires a non-volatile memory device.

The flash memory device is a non-volatile memory device capable of maintaining stored data even though power is off. Thus it will be understood to those skilled in the art that the flash memory device of performing the method of programming multi-pages according to example embodiments can be adaptable to various devices, apparatuses, and systems as well as those above mentioned.

As described above, the method of programming multi-pages according to example embodiments can simultaneously program a plurality of pages, including at least two pages pertaining to the same memory plane, thereby reducing a program time. In addition, a row-coupling disturbance can be reduced and thus performance of the flash memory device and systems including the flash memory device may be enhanced.

Furthermore, the method of programming multi-pages according to example embodiments can be performed without significantly changing the commands, and thus the flash memory device according to example embodiments can maintain compatibility with the former layout by adopting conventional peripheral circuits.

While the example embodiments of the present invention and their advantages have been described in detail, it should be understood that various changes, substitutions and alterations may be made herein without departing from the scope of the invention.

What is claimed is:

1. A method of programming multi-pages in a flash memory device, the method comprising,
forming a first page group and a second page group with respect to each of at least one memory plane by grouping page buffers such that logical odd bitlines and logical even bitlines correspond to one of the first page group and the second page group, respectively;
loading program data corresponding to at least one page coupled to a selected wordline; and
applying a program voltage to the selected wordline.

2. The method of claim 1, wherein forming the first page group and the second page group comprises:
connecting the page buffers to each of a physical odd bitline and a physical even bitline, respectively.

3. The method of claim 1, wherein memory cells coupled to adjacent physical odd and even bitlines are simultaneously programmed.

4. The method of claim 1, wherein two or more pages are simultaneously programmed with respect to a single memory plane of the at least one memory plane.

5. The method of claim 1, wherein forming the first page group and the second page group comprises:
partitioning each of the at least one memory plane into logical odd bitline blocks and logical even bitline blocks that are alternately arranged in a row direction.

6. The method of claim 5, wherein the at least one memory plane includes a first memory plane; and
wherein loading the program data corresponding to at least one page comprises:
loading first program data into the page buffers corresponding to the first page group of the first memory plane; and
loading second program data into the page buffers corresponding to the second page group of the first memory plane.

7. The method of claim 6, wherein the at least one memory plane further includes a second memory plane; and
wherein loading the program data corresponding to at least one page further comprises:
loading third program data into the page buffers corresponding to the first page group of the second memory plane.

8. The method of claim 7, wherein loading the program data corresponding to at least one page further comprises:
loading fourth program data into the page buffers corresponding to the second page group of the second memory plane.

9. The method of claim 5, wherein the at least one memory plane includes N memory planes, N being a natural number; and
wherein loading the program data corresponding to at least one page comprises:
loading the program data into the page buffers corresponding to at least one page of 2N pages, each of the 2N pages respectively corresponding to the first page groups and the second page groups of the N memory plane.

10. A flash memory device comprising:
at least one memory plane, each memory plane being partitioned into logical odd bitline blocks and logical even bitline blocks that are alternately arranged in a row direction, the logical odd bitline blocks corresponding to a first page group, the logical even bitline blocks corresponding to a second page group;
at least one first page buffer block including page buffers that are respectively connected to bitlines of the logical odd bitline blocks; and
at least one second page buffer block including page buffers that are respectively connected to bitlines of the logical even bitline blocks.

11. The flash memory device of claim 10, wherein each logical odd bitline block and each even bitline block consist of adjacent physical odd and even bitlines, respectively.

12. The flash memory device of claim 10, wherein each memory plane is partitioned into the logical odd bitline blocks and the logical even bitline blocks based on boundaries of dummy bitlines.

13. The flash memory device of claim 10, wherein the at least one memory plane includes a first memory plane; and
wherein at least one page of a first page and a second page coupled to a common wordline is simultaneously programmed, the first page pertaining to the first page group of the first memory plane, the second page pertaining to the second page group of the first memory plane.

14. The flash memory device of claim 10, wherein the at least one memory plane includes N memory planes, N being a natural number; and
wherein at least one page of 2N pages coupled to a common wordline is simultaneously programmed, the 2N pages respectively pertaining to the first page groups and the second page groups of the N memory plane.

15. The flash memory device of claim 10, wherein the first page block is disposed at an opposite position of the second page block in a column direction with respect to the corresponding memory plane.

16. The flash memory device of claim 10, wherein the first page buffer block is divided into a first sub-block connected to physical even bitlines of the first page buffer block and a second sub-block connected to physical odd bitlines of the first page buffer block; and
wherein the second page buffer block is divided into a third sub-block connected to physical even bitlines of the second page buffer block and a fourth sub-block connected to physical odd bitlines of the second page buffer block.

17. The flash memory device of claim 16, wherein the first and third sub-blocks are disposed at an opposite position of the second and fourth sub-blocks in a column direction with respect to the corresponding memory plane.

18. An apparatus comprising:
a flash memory device of performing the method of claim 1; and
a memory controller configured to control the flash memory device.
